(19) United States
(12) Patent Application Publication
(10) Pub. No.: US 2006/0286825 A1
(43) Pub. Date: Dec. 21, 2006

(54) Electrical connector with improved terminal arrangement

(76) Inventors: Yi-Tse Ho, Tainan Hsien (TW); Sheng-Wen Peng, Taipei (TW)

Correspondence Address: MOLEX INCORPORATED, 2222 WELLINGTON COURT, LISLE, IL, 60532, US

(21) Appl. No.: 11/435,949

(22) Filed: May 17, 2006

(30) Foreign Application Priority Data
Jun. 21, 2005 (TW) 094210438

(51) Int. Cl. H05K 1/00

(52) U.S. Cl. 439/65

(57) ABSTRACT

An electrical connector includes a generally rectangular housing having a pair of opposite long sides defining a long direction and a pair of short ends defining a short direction. A plurality of terminal-receiving passages are formed in the housing. The connector includes a plurality of power terminals and a plurality of signal terminals including RJ45 terminals and RJ11 terminals. The terminal-receiving passages are divided into a power terminal-receiving section and a signal terminal-receiving section spaced from each other in the long direction. The signal terminal-receiving section is divided into an RJ45 terminal-receiving section and an RJ11 terminal-receiving section spaced from each other in the short direction.

### FIELD OF THE INVENTION

This invention generally relates to the art of electrical connectors and, particularly, to an improved arrangement for mounting conductive terminals in the connector housing.

### BACKGROUND OF THE INVENTION

FIG. 1 shows a prior art electrical connector, generally designated 10, as used in a docking station for expanding computer functions. The connector is mounted on a printed circuit board 12 and includes a power terminal section, generally designated 14, and a signal terminal section 16. The signal terminal section includes common signal terminals, generally designated 18; RJ11 terminals, generally designated 20; and RJ45 terminals, generally designated 22. The RJ45 terminals are used to connect to an Ethernet connecting port, and the RJ11 terminals are used to connect to a modem connecting port.

When electrical current flows through the RJ11 terminals 20, an electromagnetic field (EMF) is produced and which interferes with the signals of the surrounding terminals. This phenomenon is called cross-talk or electromagnetic interference (EMI). The cross-talk or EMI will affect the quality of signal transmission. Therefore, common electrical design specifications require that each RJ11 terminal in this type of electrical connector be kept at a minimum distance away from other signal terminals, usually 2.54 mm.

FIG. 2 shows the footprint or terminal pattern of the prior art electrical connector as mounted on printed circuit board 12. The arrangement of the RJ11 terminals 20 between the common signal terminals 18 and the RJ45 terminals 22 can be seen. This conventional arrangement for the RJ11 terminals requires a minimum length for circuit board 12 in order to maintain the minimum distance between the RJ11 terminals and the common signal terminals as well as the RJ45 terminals. The circuit board cannot be shortened because of the distance requirements. If the distance between the RJ11 terminals and the other signal terminals is enlarged for improving the cross-talk or EMI interference, the length of the circuit board or the footprint on the circuit board must be increased. This would not be desirable in most electrical applications because of the ever-increasing miniaturization of electronic products. The present invention is directed to solving this dilemma and the problems associated therewith.

### SUMMARY OF THE INVENTION

An object, therefore, of the invention is to provide a new and improved electrical connector of the character described.

In the exemplary embodiment of the invention, an electrical connector includes a generally rectangular housing having a pair of opposite long sides defining a long direction and a pair of short ends defining a short direction. A plurality of terminal receiving passages are formed in the housing. The connector includes a plurality of power terminals, and a plurality of signal terminals including RJ45 terminals and RJ11 terminals. The terminal-receiving passages are divided into a power terminal-receiving section and a signal terminal-receiving section spaced from each other in the long direction. The signal terminal-receiving section is divided into an RJ45 terminal-receiving section and an RJ11 terminal-receiving section spaced from each other in the short direction.

According to one aspect of the invention, the RJ11 terminal-receiving section is located at an outside corner of the signal terminal-receiving section. The terminal-receiving passages in the RJ11 terminal-receiving section are in an oblique line relative to the long direction.

According to another aspect of the invention, the insulative housing includes a base portion through which the terminal-receiving passages extend. A pair of opposite side walls and a pair of opposite end walls project upwardly from the base portion. The connector is adapted for mounting on a printed circuit board, and the circuit board has terminal-receiving holes aligned with the terminal-receiving passages in the base portion of the housing.

According to a further aspect of the invention, a shielding metal shell substantially surrounds the insulative housing of the connector. In the exemplary embodiment, the shell includes a pair of shielding metal shell halves substantially covering the side walls of the housing. A shielding metal shell portion substantially covers a top of the housing spanning the side walls and end walls thereof.

Other objects, features and advantages of the invention will be apparent from the following detailed description taken in connection with the accompanying drawings.

### BRIEF DESCRIPTION OF THE DRAWINGS

The features of this invention which are believed to be novel are set forth with particularity in the appended claims. The invention, together with its objects and the advantages thereof, may be best understood by reference to the following description taken in conjunction with the accompanying drawings, in which like reference numerals identify like elements in the figures and in which:

FIGS. 1 and 2 are views of the prior art electrical connector described in the Background, above;

FIG. 3 is a perspective view of an electrical connector according to the invention, mounted on a printed circuit board;

FIG. 4 is a perspective view of the connector of FIG. 3, with the shielding metal shell removed and with the housing cut-away to show some of the signal terminals; and

FIG. 5 is a plan view showing the footprint or terminal arrangement in relation to the printed circuit board.

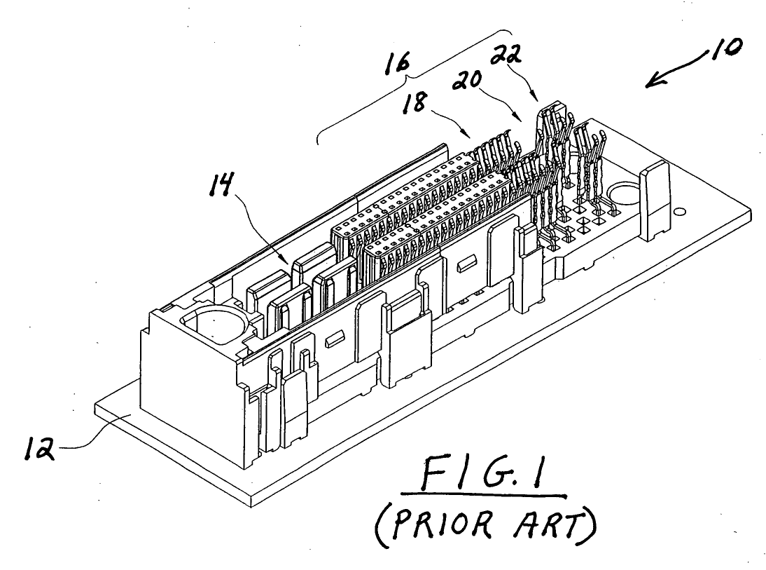

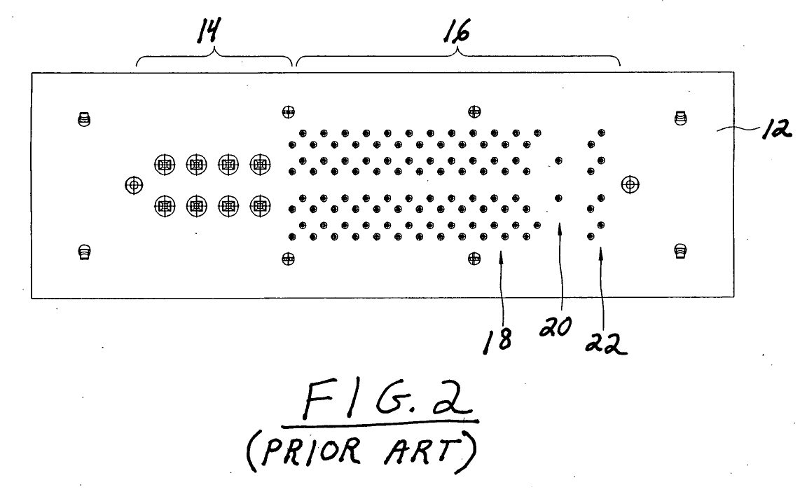

### DETAILED DESCRIPTION OF THE PREFERRED EMBODIMENT

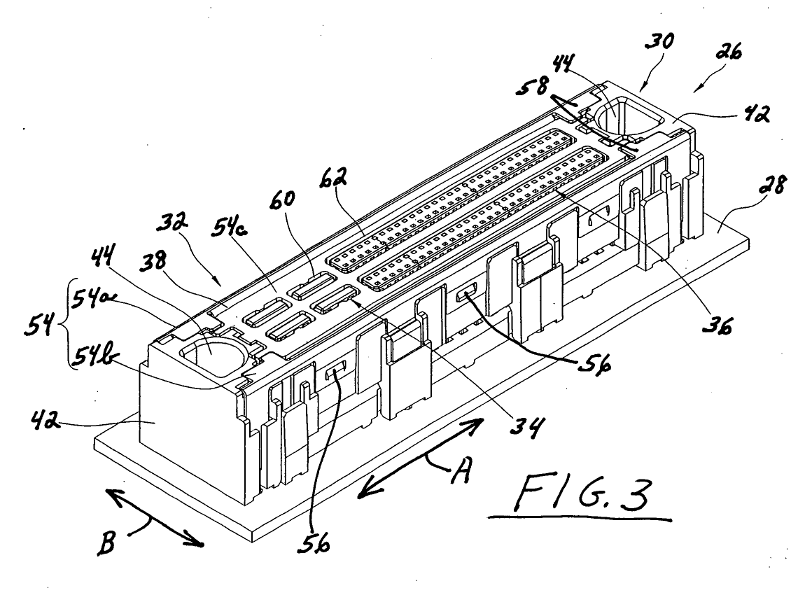

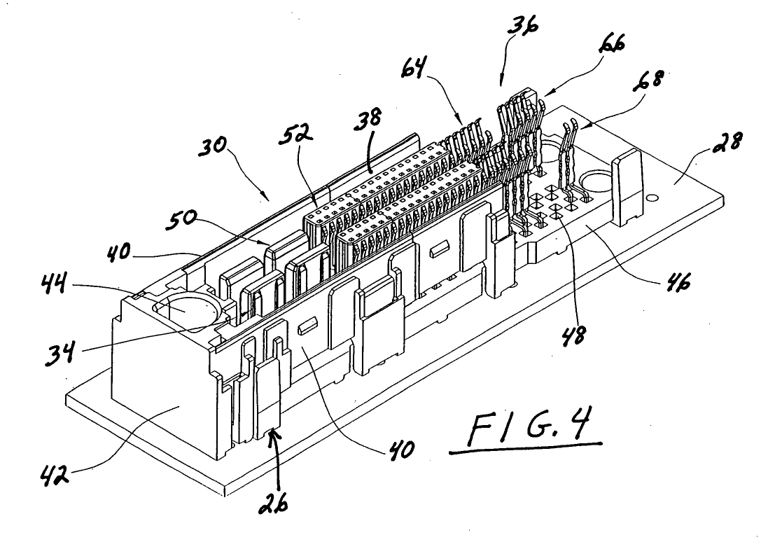

Referring to the drawings in greater detail, and first to FIGS. 3 and 4, the invention is embodied in an electrical connector, generally designated 26, which is adapted for mounting on a printed circuit board 28. The connector includes a non-conductive or insulative housing, generally designated 30, which is substantially surrounded by a shielding metal shell, generally designated 32. The housing mounts a plurality of terminals, generally designated 34 and 36. In this embodiment, terminals 34 are power terminals and terminals 36 are signal terminals.

Insulative housing 30 of connector 26 is generally rectangular and defines an upwardly-facing opening 38. This connector is designed so that the upwardly facing opening 38 extends through a bottom portion of a portable computer (not shown) which mates with a connector in a computer docking station (not shown). The housing has a pair of opposite side walls 40 at opposite long sides of the opening to define a long direction “A”. The housing has a pair of opposite end walls 42 which define opposite short ends of the opening to define a short direction “B”. A pair of locating or orienting holes 44 are formed in the end walls for orienting a mating connector in the docking station. The side walls and the end walls project upwardly from a base portion 46 of the housing. The base portion has a plurality of terminal-receiving passages 48 for receiving tail portions of the power and signal terminals 34 and 36, respectively. Finally, a plurality of support posts 50 and 52 project upwardly from base portion 46, inside opening 38, for supporting the power and signal terminals. The entire housing, including side walls 40, end walls 42, base portion 46, and support posts 50 and 52, can be a one piece structure unitarily molded of dielectric material such as plastic or the like.

Generally, a shielding metal shell 54 substantially surrounds insulative housing 30 or at least the long sides and the top of the housing. Specifically, the shielding metal shell includes a pair of shell halves 54a and 54b which are in the form of long metal plates which cover the side walls of the housing and which are latched thereto, as at 56 (FIG. 3). The metal shell also includes a top shell portion or plate 54c which spans the side walls and end walls of the housing and covers a portion of opening 38. The top shell plate rests on top of the end walls and is held in place by a plurality of flanges 58 bent inwardly from the metal shell side plates. The top shell plate has a plurality of connecting ports 60 and 62 through which access is provided to the power and signal terminals 34 and 36, respectively, by the mating connector.

Referring to FIG. 4, signal terminals 36 include a plurality of common signal terminals, generally designated 64; a plurality of RJ45 terminals, generally designated 66; and a pair of RJ11 terminals, generally designated 68. RJ45 terminals 66 and RJ11 terminals 68 are disposed toward one end of the housing spaced from power terminals 34 in the long direction “A” disposed toward another end of the housing with the common signal terminals 64 located therebetween.

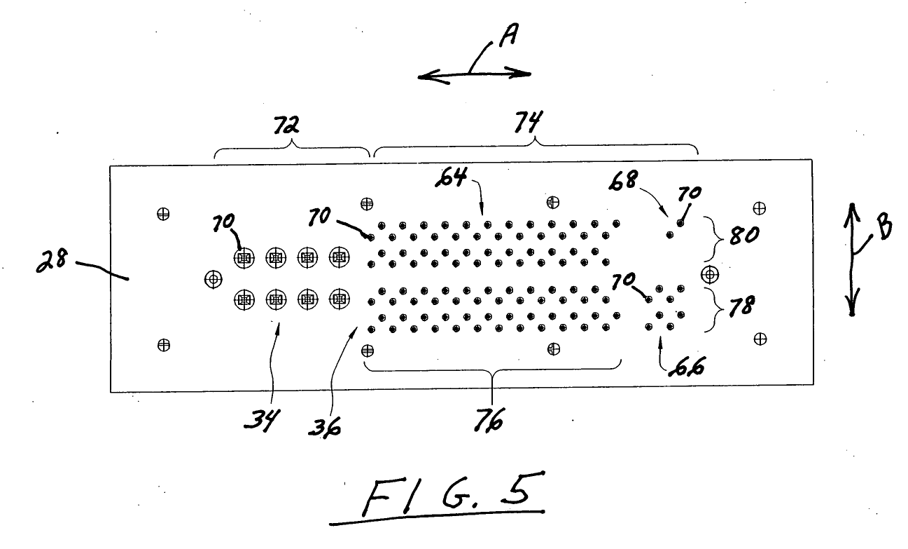

FIG. 5 shows the pattern of holes 70 in printed circuit board 28 for receiving the tail portions of all of the power terminals 34 and signal terminals 36. These holes 70 correspond to the terminal receiving passages 48 (FIG. 4) in base portion 46. In other words, the through passages 48 in the base portion of the housing are aligned with through holes 70 in the printed circuit board when connector 26 is mounted on the circuit board.

With those understandings and still referring to FIG. 5, it can be seen that passages 48 and holes 70 define a power terminal-receiving section 72. All of the passages 48 and holes 70 for signal terminals 36 define a signal terminal-receiving section 74 which is spaced from the power terminal-receiving section 72 in the long direction “A” of the connector. The passages and holes in the signal terminal-receiving section 74 further are divided into a common signal terminal-receiving section 76, an RJ45 terminal-receiving section 78, and an RJ11 terminal-receiving section 80. It can be seen that both the RJ45 terminal-receiving section 78 and the RJ11 terminal-receiving section 80 are spaced from the common signal terminal-receiving section 76 in the long direction “A” of the connector.

However, it also can be seen that the RJ45 terminal-receiving section 78 and the RJ11 terminal-receiving section 80 are spaced from each other in the short direction “B” of the connector.

Further, the RJ11 terminal-receiving section 80 is located at an outside corner of the entire signal terminal-receiving section 74. Finally, it can be seen that the passages and holes in the RJ11 terminal-receiving section are in an oblique line relative to the long direction “A”. This entire arrangement allows for the RJ11 terminals to be a farther distance from the other signal terminals, including both the common signal terminals 64 and the RJ45 terminals 66, than the distance is in the prior art. This helps to reduces crosstalk and EMI interference and, therefore, enhances the quality of signal transmission. This arrangement can be made without requiring a larger footprint on the printed circuit board or a lengthening of the connector housing.

It will be understood that the invention may be embodied in other specific forms without departing from the spirit or central characteristics thereof. The present examples and embodiments, therefore, are to be considered in all respects as illustrative and not restrictive, and the invention is not to be limited to the details given herein.

1. An electrical connector, comprising:
a generally rectangular housing having a pair of opposite long sides defining a long direction and a pair of opposite short ends defining a short direction, and a plurality of terminal-receiving passages in the housing;
a plurality of power terminals;
a plurality of signal terminals including RJ45 terminals and RJ11 terminals;
said terminal-receiving passages being divided into a power terminal-receiving section and a signal terminal-receiving section spaced from each other in said long direction; and
said signal terminal-receiving section being divided into an RJ45 terminal receiving section and an RJ11 terminal-receiving section spaced from each other in said short direction.

2. The electrical connector of claim 1 wherein said RJ11 terminal-receiving section is located at an outside corner of said signal terminal-receiving section.

3. The electrical connector of claim 2 wherein the terminal-receiving passages in said RJ11 terminal-receiving section are in an oblique line relative to said long direction.

4. The electrical connector of claim 1 wherein said insulative housing includes a base portion through which the terminal-receiving passages extend, and a pair of opposite side walls and a pair of opposite end walls projecting upwardly from the base portion.

5. The electrical connector of claim 4 wherein the base portion of said insulative housing is adapted for mounting on a printed circuit board having terminal receiving holes aligned with the terminal-receiving passages.

6. The electrical connector of claim 4, including a pair of shielding metal shell halves substantially covering the side walls of the insulative housing.

7. The electrical connector of claim 6, including a shielding metal shell portion partially covering a top of the insulative housing spanning the side walls and end walls thereof.

8. An electrical connector, comprising:
a generally rectangular housing having a pair of opposite long sides defining a long direction and a pair of opposite short ends defining a short direction, and a plurality of terminal-receiving passages in the housing;
a plurality of first terminals;
a plurality of second terminals including terminals of a first type and terminals of a second type;
said terminal-receiving passages being divided into a first section for receiving the first terminals and a second section for receiving the second terminals, the first section and the second section being disposed relative to each other in said long direction; and
said second section of terminal-receiving passages being divided into a first cluster for receiving the terminals of said first type and a second cluster for receiving the terminals of said second type, the first and second clusters of passages being disposed relative to each other in said short direction.

9. The electrical connector of claim 8 wherein said first cluster of terminal receiving passages is located at an outside corner of said second section.

10. The electrical connector of claim 9 wherein the terminal-receiving passages in said first cluster are in an oblique line relative to said long direction.

11. The electrical connector of claim 8 wherein said insulative housing includes a base portion through which the terminal-receiving passages extend and a pair of opposite side walls and a pair of opposite end walls projecting upwardly from the base portion.

12. The electrical connector of claim 11 wherein the base portion of said insulative housing is adapted for mounting on a printed circuit board having terminal receiving holes aligned with the terminal-receiving passages.

13. The electrical connector of claim 11, including a pair of shielding metal shell halves substantially covering the side walls of the insulative housing.

14. The electrical connector of claim 13, including a shielding metal shell portion partially covering a top of the insulative housing spanning the side walls and end walls thereof.

15. The electrical connector of claim 8 wherein said first terminals are common signal terminals, said first type of second terminals are RJ11 terminals and said second type of second terminals are RJ45 terminals.
